(19) United States
(12) Patent Application Publication
(10) Pub. No.: US 2024/0339340 A1
(43) Pub. Date: Oct. 10, 2024

(54) SUBSTRATE PROCESSING APPARATUS FOR PROCESSING SUBSTRATES

(71) Applicant: ASM IP Holding B.V., Almere (NL)

(72) Inventor: Jeroen Fluit, Amsterdam (NL)

(21) Appl. No.: 18/742,107

(22) Filed: Jun. 13, 2024

Related U.S. Application Data
(63) Continuation of application No. 16/202,941, filed on Nov. 28, 2018, now Pat. No. 12,040,199.

(51) Int. Cl. H01L 21/67; H01L 21/673; H01L 21/677; H01L 21/687

(52) U.S. Cl. CPC H01L 21/67098; H01L 21/67303; H01L 21/6773; H01L 21/67742; H01L 21/67751; H01L 21/67778; H01L 21/68707

(57) ABSTRACT

The disclosure relates to substrate processing apparatus, with a first and second reactor, each reactor configured with an elevator to transfer a boat with substrates to the reactor. The apparatus having a boat transfer device to transfer the boat with substrates between a substrate loading station, the first and/or second elevator and a cool down station. The substrate loading station and the cool down station may be arranged on opposite sides of the first and second elevator.

### CROSS-REFERENCE TO RELATED APPLICATIONS

This application is a continuation of, and claims priority to, U.S. patent application Ser. No. 16/202,941 filed Nov. 28, 2018 titled SUBSTRATE PROCESSING APPARATUS FOR PROCESSING SUBSTRATES, the disclosure of which is hereby incorporated by reference in their entirety.

### FIELD

The present disclosure generally relates to a substrate processing apparatus for processing a plurality of substrates. More particularly, the disclosure relates to a substrate processing apparatus, comprising a first and a second reactor for processing a plurality of substrates in a boat. The apparatus may have a first and a second elevator to transfer a boat with substrates to and from the first and second reactor respectively. The apparatus may have a substrate handling robot constructed and arranged to transfer substrates between a boat and a substrate cassette.

### BACKGROUND

Cassettes which accommodate a plurality of substrates may be transferred in a substrate processing apparatus by a cassette handler which may transfer cassettes between a cassette in-out port, a cassette station and/or a storage device. The storage device may comprise a cassette storage carousel for storing a plurality of cassettes. A substrate handling robot may be constructed and arranged to transfer substrates from a cassette at the cassette station to a substrate boat to fill the boat with multiple substrates.

To enhance productivity, the substrate processing apparatus may be provided with first and second reactors. A first or second elevator may move the filled boat into the first or second reactor respectively for processing of the substrates. After processing in the reactor the boat may be lowered with the respective elevator and cooled down. After cooling down, the processed substrates may be transferred from the boat to the cassette with the substrate handling robot.

Since there is limited space in a clean room manufacturing site where the substrate processing apparatus may be located it may be beneficial to design the width of the substrate processing apparatus as small as possible. The limited width of the substrate processing apparatus may make it possible to stack more processing apparatus side by side, tight to each other in a row.

### SUMMARY OF THE INVENTION

This summary is provided to introduce a selection of concepts in a simplified form. These concepts are described in further detail in the detailed description of example embodiments below. This summary is not intended to identify key features or essential features of the claimed subject matter, nor is it intended to be used to limit the scope of the claimed subject matter.

According to an objective it may be desirable to provide a substrate processing apparatus which has a limited width.

Accordingly there may be provided a substrate processing apparatus, comprising a first and a second reactor for processing a plurality of substrates in a boat. The apparatus may have a first elevator and a second elevator to transfer a boat with substrates to and from the first and second reactor respectively. The apparatus may have a substrate handling robot constructed and arranged to transfer substrates between a boat and a substrate cassette. The apparatus may comprise a boat transfer device to transfer boats with substrates between a substrate loading station where substrates can be transferred to the boat with the substrate handling robot, the first and/or second elevator, and a cool down station constructed and arranged to cool a boat of processed substrates. The apparatus may be constructed and arranged with the substrate loading station and the cool down station on opposite sides of the first and second elevator.

With the substrate loading station and the cool down station on opposite sides of the first and second elevator the cooling station may not add up to the width of the apparatus. The limited width may make it possible to stack more processing apparatus side by side, tight to each other in a row in a clean room manufacturing site.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1a shows a schematic top view of an example of the furnace according to an embodiment.

FIG. 1b shows an enlargement of a part of FIG. 1a.

FIG. 1c shows a side view of a part of the embodiment of FIG. 1a.

FIG. 2 shows a schematic top view of an example of the furnace according to a further embodiment.

### DETAILED DESCRIPTION OF THE FIGURES

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate.

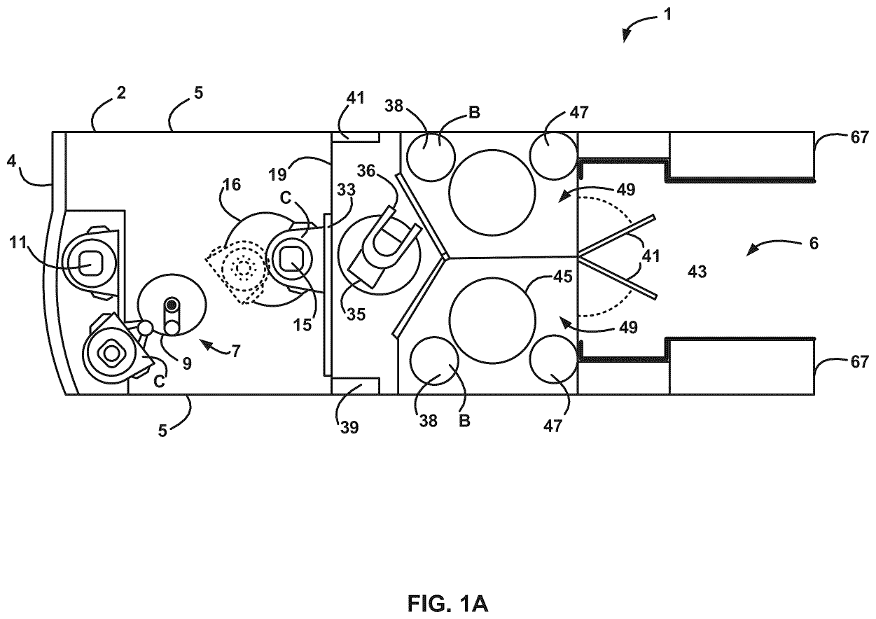

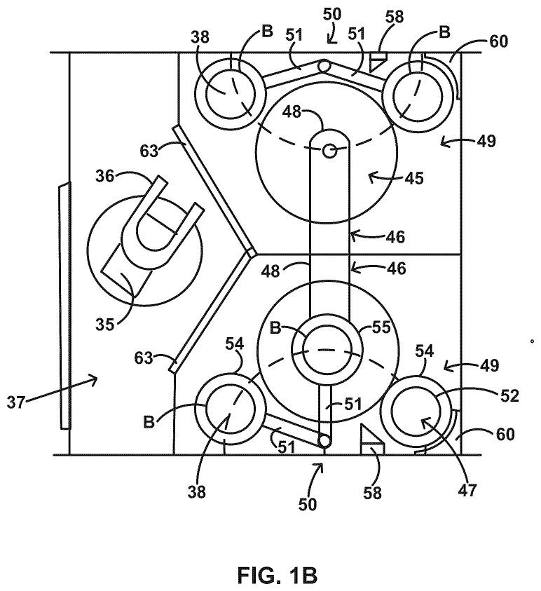

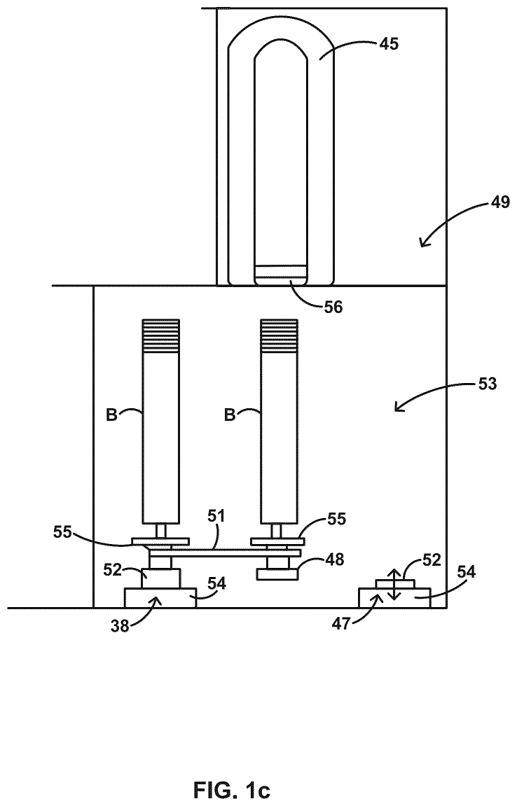

FIGS. 1a to 1c show an example of a substrate processing apparatus, e.g., furnace 1 according to an embodiment. The furnace 1 may comprise a housing 2 with a front wall 4 and a back wall 6 connected by two side walls 5 (see FIG. 1a).

The furnace 1 may comprise a storage device (not shown) such as a cassette storage carousel for storing a plurality of wafer cassettes C which wafer cassettes each accommodate a plurality of substrates. The cassette storage carousel may comprise a number of platform stages for supporting cassettes. The platform stages may be connected to a central support which is mounted rotatable around a vertical axis. Each platform stage is configured for accommodating a number of cassettes C. A drive assembly may be operatively connected to the central support for rotating the central support with the number of platform stages around the vertical axis.

The furnace 1 may have a cassette handler 7 having a cassette handler arm 9 configured to transfer cassettes C between the cassette storage carousel, a cassette in-out port 11 adjacent the front wall 4 of the housing 2 of the furnace 1, and/or a cassette station 15. The cassette handler 7 may comprise an elevating mechanism to reach to the cassettes at different height. Each platform stage for storing cassettes may have a cut-out therein the cut-out sized and shaped to allow the cassette handler arm 9 to pass vertically there through and to allow the platform stage to support a cassette C thereon.

An internal wall 19 separating the cassette handler 7 and the substrate handling robot 35 may be provided. The wall may have a closable substrate access opening 33 adjacent the cassette station 15 which may be constructed and arranged to also open the cassette C. More information with respect to the closeable substrate access opening 33 for opening cassettes may be gleaned from U.S. Pat. No. 6,481,945 incorporated herein by reference. The cassette station 15 may be provided with a cassette turntable 16 to turn the cassette C and/or to press it against the closeable substrate access opening 33.

The substrate processing apparatus may comprise a substrate handling robot 35 provided with a substrate handling arm 36 to transfer substrates. The substrates may be transferred from a cassette C positioned on the cassette station 15 through the closeable substrate access opening 33 to a substrate boat B at a substrate loading station 38 and vice versa. The furnace may comprise a substrate handling chamber 37 in which the substrate handling robot 35 is accommodated.

The furnace 1 may be provided with a first and a second reactor 45 for processing a plurality of substrates. Using two reactors may improve the productivity of the furnace 1.

The housing 2 may have a first and second side wall 5 extending over the full length of the furnace 1. The distance between the sidewalls 5 of the furnace which defines the width of the apparatus may be between 1.3 and 2, preferably between 1.5 and 1.8 and most preferably between 1.6 and 1.7 meter, for example about 1.65 meter. Maintenance of the furnace 1 may be performed from the backside 6 or front side 4 of the furnace so that there may be no need for doors in the side walls 5. The sidewalls 5 may therefore be constructed without major doors for maintenance. Multiple furnaces 1 may therefore be positioned side by side in a clean room of a semiconductor fabrication plant. The sidewalls 5 of adjacent furnaces may thereby be positioned very close together, or are even against each other.

Advantageously, the front side 4 of the multiple furnaces may form a wall which may interface with a cassette transport device in a very clean environment of a so called “clean room” having very strict requirements for particles. The back side 6 of the adjacent furnaces may interface with a maintenance alley which may have less strict requirements for particles than the front side 4. The maintenance alley may be used for maintenance from the back side of the furnace 1.

FIG. 1b shows a top view on details of a part of FIG. 1a and FIG. 1c shows a side view of a part of the FIG. 1b. FIGS. 1b and 1c show that first and second reactors 45 may be provided with first and second elevators 46 respectively. The reactors 45 and elevators 46 may be provided in a treatment module 49. The elevators may be constructed and arranged to transfer a boat with multiple substrates between a lower region 53 of the treatment module 49 and the reactors 45. Each elevator 46 may comprise a boat support arm 48 having a bearing surface configured to function as the boat support and which may be moveable in a vertical direction.

A gate valve 63 may be provided between the substrate handler 35 and the lower region of the treatment modules 49 creating a mini environment in the lower region. The substrate loading station 38 may be constructed and arranged with a boat support 54 to support the boat B with substrates in the treatment modules. A cool down station 47 constructed and arranged with a boat support 54 to support the boat with substrates to cool a boat of processed substrates may be provided in the treatment modules 49 as well. The boat supports 54 may be constructed and arranged stationary in a horizontal plane.

A boat transfer device 50 to transfer the boat with substrates between the first and second elevator 46, the substrate loading station 38, and the cool down station 47 may be provided. The boat transfer device 50 may be constructed and arranged to transfer boats B between a plurality of boat positions within the lower region while keeping the boats B vertical. The transfer may be substantially horizontal.

The boat transfer device 50 may comprises two boat transfer robots one for each reactor 45. Each boat transfer robot may be provided with two boat transfer arms 51. The boat transfer arms 51 may be rotatable to transfer the boat horizontally between the substrate loading station 38, the elevator 46 and/or the cool down station 47. The substrate loading station 38, the elevator 46 or the cool down station 47 may be moveable vertically over a short distance of for example a few centimeter to pick up the boat or drop the boat at the holder from the boat transfer arms 51. The boat supports 54 of the substrate loading station 38 and the cool down station 47 may be provided with a moveable top surface 52 to pick up the boat or drop the boat B. The boat transfer arms 51 may be provided with a holder to hold a boat. The boat B may be held vertically by the holder. Underneath the boat B a reactor door 55 may be provided which fits in the reactor opening 56 when the boat B is moved into the reactor 45. Multiple boats for example 2, 3 or 4 boats B may be used simultaneously in the furnace 1.

Alternatively, the boat transfer arms 51 may be moveable vertically over a short distance of for example a few centimeter to pick up the boat or drop the boat at the substrate loading station 38, the elevator 46 or the cool down station 47.

Alternatively, the boat transfer device 50 may comprise three or four holders for boats. By using more than two holders per reactor it becomes possible to keep the boat on a holder at the substrate loading station 38 and the cool down station 47 so that no boat support may be needed.

Alternatively, the boat transfer arms 51 may be constructed and arranged to shift the boat horizontally between the substrate loading station 38, the elevator 46 and the cool down station 47. The holder of the boat transfer arms 51 may be provided with a U shape to hold the boat. More information with respect of a boat transfer arm constructed and arranged to shift the boat may be gleaned from U.S. Pat. No. 7,198,447 incorporated herein by reference.

The substrate loading stations 38 and the cool down stations 47 may be constructed and arranged on opposite sides of the first and second elevators 46 to keep the width of the furnace 1 limited. For example, the substrate loading stations 38 may be constructed and arranged in front of the first and second elevator 46 and the cool down stations 47 may be constructed and arranged behind the first and second elevator 46 to keep the width of the furnace 1 limited.

Cool down station 47 may be used for cooling down a boat with just processed hot substrates. The cooling station 47 may be provided with a gas extractor 60 constructed and arranged to extract hot gas to cool the substrates down. The cool down station 47 may be provided with a gas inlet 58 to provide gas to the cool down station 47. The apparatus may comprise two cooling down stations 47. The gas inlet 58 and the gas extractor 60 may be fluidly connected to a pump to create a gas flow over the substrate at the cool down station. A heat exchanger may be provided to cool the gas flow and to speed up the cooling down of the substrates in the cooling down accommodation. The gas inlet 58 and the gas extractor 60 may be constructed and arranged to create a horizontal gas flow for cooling over the substrates. Alternatively, the gas inlet 58 and the gas extractor 60 may be constructed and arranged to create a downward gas flow through the minienvironment to reduce particle contamination.

The substrate processing apparatus in top view may be configured in a substantial U-shape (see FIG. 1a). The boat transfer device 50 and the reactors 45 may be constructed and arranged in the bottom part of the U-shape. A maintenance area 43 may be constructed and arranged between the legs of the U-shape. The distance between the two legs of the U-shape may be between 60 and 120 cm, more preferably between 80 and 100 cm and most preferably around 90 cm to allow enough space for a maintenance worker. A back door may be provided between the legs of the U-shape to close off the maintenance area 43 when not in use. The substantial U-shape may include a V-shape as well.

The apparatus may be constructed and arranged to allow maintenance of the reactors 45 from the maintenance area 43 to both the first and second reactor by a maintenance worker. For example, for maintenance on heating wires, heating sensors, and/or processing gas interfaces (outlets and/or inlets) of the reactors 45 by the maintenance worker. The two reactors 45 may be constructed and arranged adjacent to the same maintenance area 43 to allow maintenance of both reactors 45 from the same maintenance area 43. A maintenance door 41 may be provided to allow for maintenance. The maintenance door may be provided behind the cooling down station to allow maintenance from the back of the tool.

A maintenance worker therefore may not need to enter the housing 2 of the furnace 1 for maintenance work on the reactor 45. Risk of injury of the maintenance worker and/or contamination of the lower region and/or the reactor 45 may therefore be minimized. Maintenance from outside the housing may also improve the speed and/or accuracy of the maintenance. By using the same maintenance area 43 for both reactors 45 the total footprint of the furnace 1 in including the maintenance area 43 may be reduced.

The treatment module 49 may be provided with the maintenance door 41 openable in a direction of the maintenance area 43. Both treatment modules 49 may be provided with a separate maintenance door 41 to allow maintenance of each reactor 45 from the same maintenance area 43 by the maintenance worker. The maintenance door 41 of the treatment module 49 may also allow maintenance of the lower region of the furnace from the same maintenance area 43 for maintenance on the boat transfer device 50, the cooldown station 47, gas inlet 58, gas extractor 60, gate valves 63 elevator 46, substrate loading station 38 and/or boat B.

Alternatively, two maintenance doors may be provided per treatment module 29; a top maintenance door for giving access to the reactor 45 and a bottom maintenance door for giving access to the lower region 53 of the furnace 1.

Gate valves 63 may be provided between the substrate handling chamber 37 and the treatment modules 49. The gate valves 63 may be closed during maintenance to the substrate handling robot 35 so that one of the two treatment modules may continue working while maintaining the substrate handling robot 35 via the other treatment module.

Maintenance on one of the reactors 45 may not interfere with the other one of the reactors 45 since both are constructed as separate units. The gate valves 63 may be closed during maintenance of one reactor so that the other reactor and the substrate handling robot 35 may continue working.

The reactors 45 may have processing gas interfaces (outlets and/or inlets) which may be connected to a gas exhaust pipe or a process gas delivery system. The processing gas interfaces may be provided adjacent the maintenance area 43 so as to make them easy accessible during maintenance.

The process gas delivery system may be provided (partly) in a gas cabinet 67 constructed and arranged to provide process gas to the first and/or second reactor 45. The gas cabinet may be provided near a top of the legs of the U-shape. Providing the gas cabinet near the top of the U-shape provides easy access for maintenance. Further, this place provides flexibility if the gas cabinet needs to be adjusted or enlarged since there is space at the back of the apparatus where no critical components as substrate handling robots or cassette handlers are present.

The gas exhaust pipe may be constructed and arranged to remove process gas from at least one of the first and the second reactors and may also be provided near a top of the legs of the U-shape. Providing the gas exhaust pipe in the legs of the U-shape provides easy access for maintenance. The gas exhaust pipe may be provided with pumps and scrubbers which may require regular maintenance. Further, this place provides flexibility if the gas exhaust pipe needs to be adjusted or extended since there is space at the back of the apparatus where no critical components such as substrate handling robots and/or cassette handlers are present.

The substrate handling chamber 37 in which the substrate handling robot 35 is accommodated may be an mini-environment enclosure. The substrate handling chamber 37 may be provided with a gas inlet 39 and a gas extractor 41 which may be fluidly connected to a pump to provide a gas flow through the substrate handling chamber 37. The gas inlet 39 and the gas extractor 41 may be constructed and arranged to create a horizontal gas flow in the substrate handling chamber 37.

Alternatively, the gas inlet 39 may be provided below the gas extractor 41 to create a (partial) down flow in the substrate handling chamber 37. A down flow may be preferable because particle contamination may be minimized with down flow.

The substrate handling robot 35 may be constructed and arranged to transfer substrates in a first direction to one of the treatment modules 49 and in a second direction to another of the treatment modules 49. The first and second direction may have an angle of 90 to 180, preferably 110 to 130 and most preferably around 120 degrees with each other.

The substrate handling robot 35 may be constructed and arranged to transfer the substrate in a third direction to the cassette station 15 (in FIG. 1a). The first, second and third direction may have angles of 90 to 180, preferably 110 to 130, and most preferably around 120 degrees with each other.

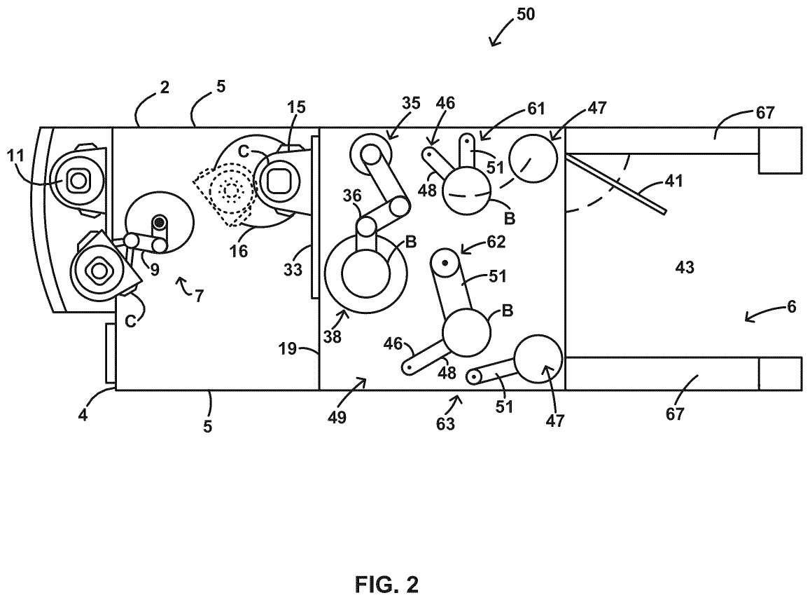

FIG. 2 shows a schematic top view of an example of a furnace according to a further embodiment which may comprise a housing 2 with a front wall 4 and a back wall 6 connected by two side walls 5. The furnace 1 may have a cassette handler 7 provided with a cassette handler arm 9 configured to transfer cassettes C between a cassette storage carousel, a cassette in-out port 11 adjacent the front wall 4 of the housing 2 of the furnace 1, and/or a cassette station 15. The cassette handler 7 may comprise an elevating mechanism to reach to the cassettes at different height.

An internal wall 19 separating the cassette handler 7 and the substrate handling robot 35 may be provided. The wall may have a closable substrate access opening 33 adjacent the cassette station 15 which may be constructed and arranged to also open the cassette C. The cassette station 15 may be provided with a cassette turntable 16 to turn the cassette C and/or to press it against the closeable substrate access opening 33.

The substrate processing apparatus may comprise a substrate handling robot 35 provided with a substrate handling arm 36 to transfer substrates. The substrates may be transferred from a cassette C positioned on the cassette station 15 through the closeable substrate access opening 33 to a substrate boat B at a substrate loading station 38 and vice versa. The substrate loading station 38 may be constructed and arranged with a boat support to support the boat with substrates. The furnace may comprise a substrate handling chamber 37 in which the substrate handling robot 35 is accommodated.

The housing 2 may have a first and second side wall 5 extending over the full length of the furnace 1. The distance between the sidewalls 5 of the furnace which may define the width of the apparatus is between 1.3 and 2, preferably between 1.5 and 1.8 and most preferably between 1.6 and 1.7 meter, for example about 1.65 meter. Maintenance of the furnace 1 may be performed from the backside 6 or front side 4 of the furnace so that there may be no need for doors in the side walls 5. The sidewalls 5 may therefore be constructed without major doors for maintenance. Multiple furnaces 1 may therefore be positioned side by side in a clean room of a semiconductor fabrication plant. The sidewalls 5 of adjacent furnaces may thereby be positioned very close together, or are even against each other.

Advantageously, the front side 4 of the multiple furnaces may form a wall which may interface with a cassette transport device in a very clean environment of a so called “clean room” having very strict requirements for particles. The back side 6 of the adjacent furnaces may interface with a maintenance alley which may have less strict requirements for particles than the front side 4. The maintenance alley may be used for maintenance from the back side of the furnace 1.

The furnace 1 may be provided with a first and a second reactor (not shown in FIG. 2 but the same as in FIGS. 1b and 1c) and provided with first and second elevators 46 configured to transfer a boat with multiple substrates between a lower region (not shown in FIG. 2 but the same as in FIGS. 1b and 1c) and the reactors. Each elevator 46 may comprise a boat support arm 48 having a bearing surface configured to function as the boat support and which may be moveable in a vertical direction. The reactors and elevators 46 may be provided in a treatment module.

A cool down station 47 constructed and arranged with a boat support to support the boat with substrates to cool a boat of processed substrates may be provided in the treatment modules 49.

A boat transfer device 50 to transfer the boat with substrates between the first and second elevator 46, the substrate loading station 38, and the cool down station 47 may be provided in the treatment module 49. The boat transfer device 50 may be constructed and arranged to transfer boats B between a plurality of boat positions within the lower region while keeping the boats B vertical. The transfer may be substantially horizontal.

The boat transfer device 50 may comprises three boat transfer robots 61, 62, 63. Each boat transfer robot may be provided with a single boat transfer arm 51. The boat transfer arm 51 may be rotatable to transfer the boat horizontally between the substrate loading station 38, one of the elevators 46 and/or the cool down station 47. The substrate loading station 38, the elevator 46 or the cool down station 47 may be moveable vertically over a short distance of for example a few centimeter to pick up the boat or drop the boat at the holder from the boat transfer arms 51. The boat supports of the substrate loading station 38 and the cool down station 47 may be provided with a moveable top surface to pick up the boat or drop the boat B. The boat transfer arm 51 may be provided with a holder to hold a boat. The boat B may be held vertically by the holder. Multiple boats for example 2, 3 or 4 boats B may be used simultaneously in the furnace 1.

The substrate loading station 38 and the cool down stations 47 may be constructed and arranged on opposite sides of the first and second elevators 46 to keep the width of the furnace 1 limited. The substrate loading station 38 may be constructed and arranged in front of the first and second elevator 46. The cool down stations 47 may be constructed and arranged stationary behind the first and second elevator 46.

Cool down station 47 may be used for cooling down a boat with just processed hot substrates. The cooling station 47 may be provided with a gas extractor constructed and arranged to extract hot gas to cool the substrates down. The cool down station 47 may be provided with a gas inlet to provide gas to the cool down station 47. The apparatus may comprise two cooling down stations 47. The substrate processing apparatus in top view may be configured in a substantial U-shape (see FIG. 2).

The boat transfer device 50 and the reactors may be constructed and arranged in the bottom part of the U-shape. A maintenance area 43 may be constructed and arranged between the legs of the U-shape. The distance between the two legs of the U-shape may be between 60 and 120 cm, more preferably between 80 and 100 cm and most preferably around 90 cm to allow enough space for a maintenance worker. A back door 41 may be provided between the legs of the U-shape to close off the maintenance area 43 when not in use. The substantial U-shape may include a V-shape as well.

The apparatus may be constructed and arranged to allow maintenance from the maintenance area 43 to both the first and second reactor by a maintenance worker. For example, for maintenance on heating wires, heating sensors, and/or processing gas interfaces (outlets and/or inlets) of the reactors by the maintenance worker. The two reactors may be constructed and arranged adjacent to the same maintenance area 43 to allow maintenance of both reactors from the same maintenance area 43. A maintenance door 41 may be provided to allow for maintenance. The maintenance door may be provided behind the cooling down station to allow maintenance from the back of the tool.

A maintenance worker therefore may not need to enter the housing 2 of the furnace 1 for maintenance work on the reactor. Risk of injury of the maintenance worker and/or contamination of the lower region and/or the reactor may therefore be minimized. Maintenance from outside the housing may also improve the speed and/or accuracy of the maintenance. By using the same maintenance area 43 for both reactors the total footprint of the furnace 1 in including the maintenance area 43 may be reduced.

The treatment module 49 may be provided with one maintenance door 41 openable in a direction of the maintenance area 43. The treatment modules 49 may be provided with a separate maintenance door 41 to allow maintenance of each reactor from the same maintenance area 43 by the maintenance worker. The maintenance door 41 of the treatment module 49 may also allow maintenance of the lower region of the furnace from the same maintenance area 43 for maintenance on the boat transfer device 50, the cooldown station 47, gas inlet, gas extractor, elevator 46, substrate loading station 38 and/or boat B.

Alternatively, two maintenance doors may be provided per treatment module 49. For example, a top maintenance door for giving access to the reactor and a bottom maintenance door for giving access to the lower region of the furnace 1.

The reactors 45 may have processing gas interfaces (outlets and/or inlets) which may be connected to a gas exhaust pipe or a process gas delivery system. The processing gas interfaces may be provided adjacent the maintenance area 43 so as to make them easy accessible during maintenance.

The process gas delivery system may be provided (partly) in a gas cabinet 67 constructed and arranged to provide process gas to the first and/or second reactor 45. The gas cabinet may be provided near a top of the legs of the U-shape. Providing the gas cabinet near the top of the U-shape provides easy access for maintenance. Further, this place provides flexibility if the gas cabinet needs to be adjusted or enlarged since there is space at the back of the apparatus where no critical components as substrate handling robots or cassette handlers are present.

The gas exhaust pipe may be constructed and arranged to remove process gas from at least one of the first and the second reactors and may also be provided near a top of the legs of the U-shape. Providing the gas exhaust pipe in the legs of the U-shape provides easy access for maintenance. The gas exhaust pipe may be provided with pumps and scrubbers which may require regular maintenance. Further, this place provides flexibility if the gas exhaust pipe needs to be adjusted or extended since there is space at the back of the apparatus where no critical components such as substrate handling robots and/or cassette handlers are present.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

1. A substrate processing apparatus, comprising:
a first reactor in a first treatment module for processing a plurality of substrates in a boat;
a second reactor in a second treatment module for processing a plurality of substrates in a boat;
a first elevator to transfer a boat with substrates to and from the first reactor;
a second elevator to transfer a boat with substrates to and from the second reactor;
a first cool down station in the first treatment module, where the first cool down station is constructed and arranged to cool a boat of processed substrates;
a substrate handling robot constructed and arranged to transfer substrates between a boat at a first substrate loading station and a substrate cassette; and
a first gate valve between the substrate handling robot and the first elevator to create a first minienvironment in the first treatment module,
wherein the apparatus is constructed and arranged with the first substrate loading station and the first cool down station on opposite sides of the first elevator.

2. The substrate processing apparatus according to claim 1, a first boat transfer device to transfer boats with substrates between:
the first substrate loading station,
the first elevator; and,
the first cool down station.

3. The substrate processing apparatus according to claim 1, further comprising a second gate valve between the substrate handling robot and the second elevator to create a second minienvironment in the second treatment module.

4. The substrate processing apparatus according to claim 1, further comprising a second substrate loading station,
wherein the substrate handling robot is constructed and arranged to transfer substrates between a boat at the first substrate loading station or the second substrate loading station and the substrate cassette.

5. The substrate processing apparatus according to claim 4, further comprising a second cooling down station in the second treatment module, where the second cool down station is constructed and arranged to cool a boat of processed substrates.

6. The substrate processing apparatus according to claim 2, a second boat transfer device to transfer boats with substrates between:
the second substrate loading station,
the second elevator; and,
the second cool down station.

7. The substrate processing apparatus according to claim 1, wherein the first substrate loading station is constructed and arranged in front of the first elevator and the first cool down station behind the first elevator.

8. The substrate processing apparatus according to claim 7, wherein a first maintenance door is provided behind the first cooling down station to allow maintenance from the back of the tool.

9. The substrate processing apparatus according to claim 8, wherein the second substrate loading station is constructed and arranged in front of the second elevator and wherein a second maintenance door is provided behind the second cooling down station to allow maintenance from the back of the tool.

10. The substrate processing apparatus according to claim 1, wherein the first minienvironment is provided with a first gas inlet and a first gas extractor which is fluidly connected to a first pump to provide a first gas flow through the first minienvironment.

11. The substrate processing apparatus according to claim 3, wherein the first minienvironment is provided with a first gas inlet and a first gas extractor to provide a first gas flow through the first minienvironment, and wherein the second minienvironment is provided with a second gas inlet and a second gas extractor to provide a second gas flow through the second minienvironment.

12. The substrate processing apparatus according to claim 1, further comprising a substrate handling chamber with a third minienvironment, wherein the substrate handling robot is provided within the substrate handling chamber, wherein the substrate handling chamber is provided with a third gas inlet and a third gas extractor to provide a third gas flow through the third minienvironment.

13. The substrate processing apparatus according to claim 1, further comprising:
a cassette handler provided with a cassette handler arm configured to transfer cassettes between a cassette station;
a cassette in-out port;
a cassette storage; and
a wall separating the cassette handler and the substrate handling robot, the wall having a closable substrate access opening adjacent the cassette station;
wherein the cassette storage includes a plurality of platform stages for supporting cassettes, wherein each platform stage comprises at least one cut-out therein, the cut-out sized and shaped to allow the cassette handler arm to pass vertically there through and to allow each platform stage to support the cassette thereon.

14. The substrate processing apparatus according to claim 2, wherein the first boat transfer device comprises a first boat transfer arm provided with a boat support configured to support the substrate boat and constructed and arranged to be moveable in a horizontal direction.

15. The substrate processing apparatus according to claim 14, wherein the first boat transfer device comprises a second boat transfer arm.

16. The substrate processing apparatus according to claim 6, wherein the first boat transfer device comprises a first boat transfer arm and a second boat transfer arm, and wherein the second boat transfer device comprises a third boat transfer arm and a fourth boat transfer arm.

17. The substrate processing apparatus according to claim 15, wherein the first boat transfer device comprises three or four holders for boats.

18. The substrate processing apparatus according to claim 16, wherein the first boat transfer device comprises three or four holders for boats, and wherein the second boat transfer device comprises three or four holders for boats.
